(19) United States
(12) Patent Application Publication
(10) Pub. No.: US 2024/0160233 A1
(43) Pub. Date: May 16, 2024

(54) POWER MODULE WITH DETECTION OF AGING

(71) Applicant: Robert Bosch GmbH, Stuttgart (DE)

(72) Inventors: Jan Homoth, Reutlingen (DE); Sebastian Strache, Wannweil (DE); Josef Goeppert, Kusterdingen (DE)

(21) Appl. No.: 18/548,435

(22) PCT Filed: Mar. 2, 2022
(86) PCT No.: PCT/EP2022/055254

§ 371 Date: Oct. 3, 2023

(30) Foreign Application Priority Data
Mar. 5, 2021 (DE) 10 2021 202 150.6

(51) Int. Cl. G05D 23/24; H05K 7/20

(52) U.S. Cl. CPC G05D 23/24; H05K 7/20945

(57) ABSTRACT

A power module. The power module has a substrate and at least one power transistor situated on a lower side of the substrate, and at least one temperature sensor situated in the power module. At least one primary temperature sensor is situated on an upper side opposite the at least one power transistor or in an inner substrate layer situated above the at least one power transistor. At least one reference temperature sensor for providing a comparison temperature is situated at a distance from all power transistors, on the upper side or on one of the inner substrate layers. As a result, the transistor temperature can be measured closer to the source of the heat and a reference temperature is provided for detecting resistance changes due to material aging.

### FIELD

The present invention relates to a power module including a substrate and at least one power transistor situated on the substrate, and at least one temperature sensor situated in the power module.

### BACKGROUND INFORMATION

Power modules generate large amounts of heat in a highly localized manner, which can greatly reduce the life of the power module if not adequately cooled/down-regulated. At the same time, it is difficult to provide targeted cooling as needed in larger arrays of power modules or to measure the temperature of the individual power transistors without major delay, and to maintain an overview of how strongly the individual power modules or power semiconductors/power transistors are loaded.

Temperature detection is implemented in power modules in different ways:
NTC (Negative Temperature Coefficient) or PTC (Positive Temperature Coefficient) resistors are situated in the power module near the power transistors and the temperature is determined by measuring the temperature-dependent resistances,
Detection of the temperature via specific component configurations (diodes/resistors) on the substrate,
Use of temperature-sensitive, electrically measurable characteristics of the power transistors to directly ascertain the temperature of the respective power transistor.

However, the above solutions are either inaccurate and/or have a significant time delay in the measurement of a temperature peak due to their distance from the hottest location, or they require a significantly complicated design of the power transistor. Furthermore, temperature sensors of this type cannot simultaneously directly measure the influence of aging on the module.

Furthermore, power modules currently do not have any special structures or sensors that provide information about the remaining useful life (RUL). The power modules must therefore be (over)designed in such a way that the quality targets are always guaranteed, even under extreme stresses and manufacturing tolerances.

### SUMMARY

According to the present invention, a power module of the general type mentioned above is provided. According to an example embodiment of the present invention, at least one primary temperature sensor is situated on a side of the substrate opposite the at least one power transistor or in an inner substrate layer situated above or below the at least one power transistor, and at least one reference temperature sensor for providing a comparison temperature is situated at a distance from all power transistors on a side of the substrate or on one of the inner substrate layers.

The situation of the primary temperature sensor according to the present invention has the advantage that the temperature is measured much closer than before to the at least one power transistor, and thus to the source of the heat loss. This can prevent a power transistor from heating up too strongly before the heat reaches the conductor loop by thermal conduction, as can occur in the related art due to the larger spacing. Any significant exceeding of the operating temperature usually reduces the useful life of the individual power transistor.

In power modules with a plurality of power transistors, in addition there is some probability that one power transistor will heat up more frequently and more strongly on average than the other power transistors and will thus be the first to fail. Also, due to manufacturing tolerances, one power transistor may heat up more than another power transistor of the same type at the same load. A failure of a power transistor, however, often has the result that the entire power module has to be replaced. The solution according to the present invention therefore enables significantly better monitoring of the temperature load on the individual power transistors and, if necessary, counter-controlling of the load in order to increase the overall useful life of the power module.

According to an example embodiment of the present invention, preferably, at least one temperature sensor (preferably all temperature sensors) includes a temperature-dependent resistor, e.g., at least one conductor loop each, having temperature-dependent resistance. This has the advantage that not only the actual temperature can be measured, but also material aging in the area of the temperature-dependent resistance can be measured via significant changes in resistance. The latter, however, requires a temperature comparison value (or resistance comparison value) for reliable detection, because otherwise a gradual or sudden increase in resistance due to material aging could also be misinterpreted as a too-high or too-low (PTC or NTC) temperature. Temperature sensor, here and in the rest of the application, can refer to the at least one primary temperature sensor or at least one reference temperature sensor.

However, the reference temperature sensor(s) can in principle be situated at any position in the substrate, as long as it is not directly opposite a power transistor. For example, a reference temperature sensor may also extend along an edge of the substrate or be situated in a corner of the substrate.

Accordingly, the reference temperature sensor should be situated at a location on the power module that is affected as little as possible by (temperature-caused) aging. At the same time, the reference temperature sensor should still be situated close enough to the main heat sources of the power module (in the case of large power modules) that the heat conduction up to the reference temperature sensor takes place sufficiently fast so that a temperature equilibrium can be established in a standard operating situation. Thus, the phrase “at a distance from all power transistors” should be understood to mean that the reference temperature sensor is not situated directly above a power transistor and is not situated directly adjacent to a power transistor in the plane of the substrate. The reference temperature sensor could also preferably be integrated into the ASIC or realized by a different sensor technology (e.g. NTC).

Due to the different aging of the primary temperature sensor and the reference temperature sensor as a result of the different temperature loads, there is a gradual temporal increase in the difference between the temperatures determined in each case (temporal drift). The power module can be designed to issue a warning about the remaining useful life to be expected (e.g. less than 1 year, less than 1 month, etc.) when a time-averaged relative temperature difference is exceeded, e.g. (∫dt|T_{primary}−T_{reference}|/T_{reference})/t_{averaging}>limit value. The power module can also use a plurality of such limit values, each of which can correspond to different remaining power module useful lifespans.

According to an example embodiment of the present invention, preferably, the power module is designed to calculate corrected temperature measurement values of the primary temperature sensor (or primary temperature sensors) through comparison with the temperature measured by the reference temperature sensor. Preferably, at least one calibration curve is used here, i.e. an expected temperature ratio between the respectively measured temperature of the respective (primary) temperature sensor and of the reference temperature sensor.

By comparing the measured temperature of the at least one primary temperature sensor with the measured temperature of the reference temperature sensor, the temporal development of the drift of the primary temperature sensor can be indirectly ascertained. This information can then be used to ascertain the remaining useful life.

Due to the periodic adjustment with the reference temperature sensor, an aging of the power module can be detected at an early stage. This allows a response thereto to be made before a fatal failure occurs. In an electric vehicle application in the charging electronics, a proactive replacement of the power module (there e.g. as an inverter) can prevent the vehicle from stalling, which would be an important advantage especially for use in autonomous vehicles. Alternatively, the power of the power module, or only of individual power transistors, can be reduced to increase the remaining useful life or to replace the power module during the next regular vehicle service.

Thus, a dual benefit of the present invention (temperature sensing and degradation detection) is that this additional information is acquired without additional sensor outlay and costs.

According to an example embodiment of the present invention, the substrate is preferably a multilayer substrate, so that the power wiring, the logic wiring (e.g. control lines for power transistors) and the temperature sensors (e.g. their conductor loops) required for temperature measurement can be integrated. For example, the underside of the substrate can be the lowest layer of the substrate, or at least the lowest layer with conductive elements. Accordingly, the top surface of the substrate can be, for example, the uppermost layer of the substrate on which conductive elements are situated. For example, the power transistor(s) may be situated on the lower side, while the associated primary temperature sensor(s) are situated on an upper side opposite a power transistor, or in a substrate layer situated above the respective power transistor.

The terms “lower side,” “upper side” and “side,” or “below” and “above,” and the like, are used in this application only for the relative orientation of the components and are not to be understood as limiting.

Advantageous further developments of the present invention are disclosed herein.

According to an example embodiment of the present invention, preferably, at least one primary temperature sensor has a conductor loop for temperature measurement situated on the side of the substrate opposite the power transistor or in an inner substrate layer situated above or below the at least one power transistor. This conductor loop preferably has a temperature-dependent resistance, so that both the instantaneous temperature of the power transistor can be monitored and material aging of the substrate can be detected by an abrupt and permanent change in resistance (e.g. when there is a deformation of the conductor loop or a crack in the conductor loop).

A conductor loop of a primary temperature sensor can be situated opposite an entire power transistor or only a portion of the power transistor. If a plurality of power transistors are connected to a substrate, each power transistor is preferably provided with its own conductor loop (each of a primary temperature sensor) above the respective power transistor, e.g. in/on an inner layer or the upper side of the substrate. However, the individual conductor loops can then be connected to common evaluation electronics (for example, an application-specific integrated circuit, ASIC, of the power module).

Preferably, according to an example embodiment of the present invention, at least one conductor loop has a meandering course. This makes it possible to increase the conductor path under the influence of the increased temperature and thus, for example, to achieve the greatest possible absolute effect on the resistance of the conductor loop.

Preferably, according to an example embodiment of the present invention, at least one conductor loop of a primary temperature sensor is situated opposite the source of the power transistor. In a field-effect transistor, the source is usually the strongest heat source due to its proximity to the active region of the transistor, and the conductor loop can therefore be placed only opposite the source for optimum sensitivity. Since local peak temperatures can cause long-term damage, these are a much better indicator of problematic overheating and material aging than the average temperature of the power transistor. It is therefore advantageous to specifically measure the temperature of the usually hottest point on the power transistor.

In one example embodiment of the present invention, at least one conductor loop extends over a plurality of substrate layers. This allows the accuracy of the temperature measurement to be increased. At least one conductor loop can have a meandering course in a plurality of substrate layers. At least one conductor loop can be connected to the various substrate layers via vias.

According to an example embodiment of the present invention, it is preferred if the power module has at least one application-specific integrated circuit (ASIC) connected to at least one power transistor as well as to the at least one primary temperature sensor associated with the power transistor, and to the reference temperature sensor. For example, the ASIC can then use single-gate controlling to regulate the individual power transistors in order to equalize the temperature load on the power transistors (instantaneously or over time) and thus to increase the overall useful life or performance of the power module. The ASIC can be situated on the lower side or the upper side of the substrate. In the latter case, the temperature sensors or conductor loops can be connected to the ASIC via vias, for example.

In one specific example embodiment of the present invention, the application-specific integrated circuit is designed to calculate a measure of the aging of the power transistor via the comparison of the temperature data provided by at least one primary temperature sensor and the reference temperature sensor. For example, the integrated circuit can be designed to calculate a temperature difference between the at least one primary temperature sensor and the reference temperature sensor and to compare it to a comparison difference curve from calibration data in order to detect deviations and thus premature aging of a power transistor. Over time, the primary temperature sensor adjacent to the power transistor drifts away from its characteristic at the time of calibration (e.g. because the resistance increases due to material change), while this is significantly less the case for the reference temperature sensor. The measured temperature difference can be a temperature difference averaged over a period of time in order to reduce delays due to heat conduction effects. Alternatively, a temperature difference can be used to determine age only after it has fluctuated by less than a prespecified temperature (e.g. by less than 5° C.) over a minimum period of time (e.g. one minute). If the resistance of a primary temperature sensor exceeds a first threshold value (indicating significant aging), the associated power transistor can be down-regulated by the ASIC. If a second (higher) threshold value is exceeded, the associated power transistor can be switched off as defective. Preferably, the ASIC is designed to output an error message in the latter case (or in both cases).

Preferably, according to an example embodiment of the present invention, the application-specific integrated circuit is connected to at least two power transistors as well as to the at least two corresponding primary temperature sensors. It is preferred if at least two power transistors are situated on the lower side of the substrate, a separate conductor loop for temperature measurement in each case being situated above the respective power transistor in an inner layer or on the upper side of the substrate. Preferably, a separate conductor loop is provided for each power transistor, for example, three, four, five, six or more power transistors and conductor loops of the same power module.

In one example embodiment of the present invention, the application-specific integrated circuit is designed to control the load on the at least two power transistors so that the temperature measured via the primary temperature sensors is as close to equal as possible. This solution is as simple as possible, since it is not absolutely necessary to store a “temperature history” for the individual power transistors in order to decide which power transistor can and should be loaded more. It is then possible to simply down-regulate, during operation, the power transistor(s) whose temperature(s) is/are above an upper temperature threshold (a problematic temperature, or above a problematic resistance), and to up-regulate those power transistors whose temperature is below a lower temperature threshold value (an unproblematic temperature). The use of two different threshold values can stabilize the regulation in order to avoid frequent up-regulation and down-regulation. The threshold values can preferably be adjusted by comparison with the reference temperature sensor in order to compensate for the temporal drift (i.e. in particular the measurement error of the primary temperature sensors, which increases with material aging).

According to an example embodiment of the present invention, it is preferred if the power module has at least one primary temperature sensor situated on a side of the substrate opposite the at least one application-specific integrated circuit or in an inner substrate layer situated below or above the at least one application-specific integrated circuit. The application-specific integrated circuit is also a heat source in the power module and can in principle fail prematurely due to material aging as a result of temperature fluctuations. At the same time, the primary temperature sensor can be used to control the cooling capacity of an active cooling device (e.g. water cooling) of the power module.

In one example embodiment of the present invention, the application-specific integrated circuit is designed such that it controls the load of the at least two power transistors such that the temperatures measured via the primary temperature sensors are as close to equal as possible. This can optimize the overall useful life by reducing the probability of premature failure of one of the power transistors. Particularly preferably, the temperatures measured via the primary temperature sensors are first corrected by a comparison with the temperature measured by the reference temperature sensor. Here, one or more calibration curve(s) can be used to estimate an actual temperature of the power transistors.

Preferably, according to an example embodiment of the present invention, the application-specific integrated circuit is designed such that it controls at least one active cooling device of the power module such that all temperatures measured via the primary temperature sensors remain below a temperature limit value. Preferably, temperature measured values corrected via calibration curves are used here.

According to an example embodiment of the present invention, preferably, the power module has at least one primary temperature sensor having at least one conductor loop attached to a load zone of the substrate, the conductor loop being connected to the application-specific integrated circuit, the application-specific integrated circuit being designed to calculate a measure of aging or damage of the load zone from a temporal development of the electrical resistance of the conductor loop. Regions of the substrate without an active heat source can also experience premature material aging, e.g. because they are exposed to strong temperature gradients during operation, i.e. are situated between one or more heat sources and a cooler region of the substrate. Such a primary temperature sensor is therefore preferably also not used for temperature measurement (even if this is possible); rather, the resistance of the conductor loop is compared with that of the conductor loop of the reference temperature sensor at regular intervals in order to detect potential material aging (and thus resistance increases compared to an expected resistance value).

According to an example embodiment of the present invention, preferably, the power module has at least one power semiconductor, and at least one primary temperature sensor situated on a side of the substrate opposite the at least one power semiconductor or in an inner substrate layer situated above or below the at least one power semiconductor. The power semiconductors can be, for example, power diodes, thyristors, or triacs.

In one example embodiment of the present invention, the power module has a plurality of power semiconductors embedded between substrate layers. Here, the power module preferably has only one substrate with a plurality of substrate layers. The power semiconductors can be situated in an inner substrate layer and embedded or sandwiched between further substrate layers from both sides.

In one example embodiment of the present invention, the power module has a plurality of power semiconductors embedded between two substrates, conductor loops for temperature measurement (of primary temperature sensors or reference temperature sensors) being situated in at least one of the substrates. These power semiconductors are preferably embedded “upside down” in the substrate so that the source surface is on the underside. In this case, the conductor loops (the meander structures) would be situated “below” the power transistors (e.g. MOSFETs). Thus, in addition to the power transistor(s), the power module also includes a plurality of power semiconductors whose temperature can also be measured with one or more conductor loops (additional primary temperature sensors).

According to an example embodiment of the present invention, it is preferred if the substrate is or has a multilayer Low Temperature Cofired Ceramics (LTCC). With such a substrate, it is easily possible to provide additional conductor loops (primary temperature sensors) for temperature measurement on the upper side opposite the lower side having the power transistors, or in the inner layers, without significantly complicating the manufacturing processes.

In one example embodiment of the present invention, the temperature measurement in at least one conductor loop takes place using a four-point measurement or a band-end alignment. These measurement methods increase the accuracy of the measurement without significantly complicating the structure. However, a different course of the conductor loop and corresponding connections to the evaluation electronics (e.g. local ASIC) may then be required.

In one example embodiment of the present invention, a plurality of conductor loops are situated in different substrate layers and connected in series. This allows the length of the conductor loop to be maximized in the hot area. In this way, the resistance change when there is a temperature change, and as a result of material changes in the substrate, is also increased. The measurement sensitivity for both is thus increased.

In one example embodiment of the present invention, the power module has at least two substrates. A power wiring and the temperature sensors/conductor loops for temperature measurement can be situated in one of the two substrates (e.g. in different substrate layers).

Compared to classical configurations (NTC) of the temperature sensor/conductor loop next to a power transistor/power semiconductor on a lower substrate, according to the present invention the conductor loop is situated very close to the hotspot and not in the cooling path. This allows the maximum temperature of the power semiconductor to be measured with a high degree of accuracy. At the same time, the reference temperature sensor allows more accurate determination of the actual temperature by the individual temperature sensors and better aging detection of the power module components.

According to an example embodiment of the present invention, preferably, at least one primary temperature sensor and at least one reference temperature sensor are connected in a Wheatstone bridge. A plurality of primary temperature sensors (e.g. two or three) may also be connected to the reference temperature sensor in a Wheatstone bridge. However, one or two reference resistors can also be used together with the primary temperature sensor and the reference temperature sensor. The configuration in a Wheatstone bridge fundamentally increases the accuracy of the resistance comparison for temperature correction, aging detection or humidity detection.

According to an example embodiment of the present invention, preferably, the application-specific integrated circuit is designed to detect the presence of moisture on or in the power module via a resistance measurement between two conductor loops. A sudden or gradual reduction in resistance between two originally electrically isolated conductor loops can provide an indication of a moisture buildup that is occurring, before damage to the power module results due to a short-circuit of the transistor. Preferably, the ASIC regularly measures the electrical resistance between different pairs of two conductor loops (of the primary temperature sensors or of the reference temperature sensor), which are ideally situated in close spatial proximity but are insulated from each other by an insulating material. For example, a packaging (also called mold) of the power module or the substrate/a substrate layer (e.g. LTCC ceramic) itself acts as an insulator. Via the ASIC, a voltage is applied between the conductor loops thus insulated, and the resulting current is measured in order to determine the resistance. The resistance now changes as a function of the moisture content of the insulating material and is further used as a sensor signal for the integrity of the power module (in particular of the packaging and the substrate layers). A reduction in the resistance below a predetermined threshold (e.g., below 1 GΩ, 100 MΩ, 10 MΩ, or 1 MΩ) can preferably be used by the ASIC to detect problematic moisture ingress. Failures can thus be detected in advance, before the moisture induces a hardware failure. For example, when using the area to be measured on the upper side of the substrate, the moisture of the packaging-to-substrate interface is measured. This is an excellent way to detect moisture ingress, e.g. due to delamination. When using the area to be measured inside the substrate (e.g. at least one conductor loop on an inner layer of the substrate), the diffusive moisture loading is primarily measured. Preferably, the ASIC is designed to regularly measure the resistance between a plurality of different pairs of conductor loops in order to provide moisture detection in a plurality of areas of the power module.

According to an example embodiment of the present invention, preferably, the power module has an edge conductor loop extending substantially along an outer edge of the plane of the substrate, the application-specific integrated circuit being designed to detect, via regular resistance measurements of the edge conductor loop, the presence of a break in the outer edge of the substrate through an increase in resistance. By the plane of the substrate is meant here, for example, a substantially planar rectangular shape of the power module. The application-specific integrated circuit can be designed to detect the presence of a break in the outer edge of the substrate through an increase in resistance via regular resistance measurements of the edge conductor loop. The edge conductor loop can be the conductor loop of the reference temperature sensor or an additional conductor loop that is primarily used for break detection.

Break detection by means of resistance measurement and detection of abrupt rises above a resistance threshold (e.g. 1 MΩ) in individual conductor loops can, however, also be used in any other conductor loop of the power module (e.g. for conductor loops assigned to the power transistors).

### BRIEF DESCRIPTION OF THE DRAWINGS

Exemplary embodiments of the present invention are shown on the basis of the figures and are explained in more detail in the following description.

FIG. 1 shows a first example embodiment of a power module according to the present invention in a view from the upper side of the power module.

FIG. 2 shows a second example embodiment of a power module according to the present invention in cross-sectional view.

FIG. 3 shows a second example embodiment of a power module according to the present invention in a view from the upper side of the power module.

FIG. 4 shows examples of resistance curves over time when a break occurs in the power module or when liquid is stored.

### DETAILED DESCRIPTION OF EXAMPLE EMBODIMENTS

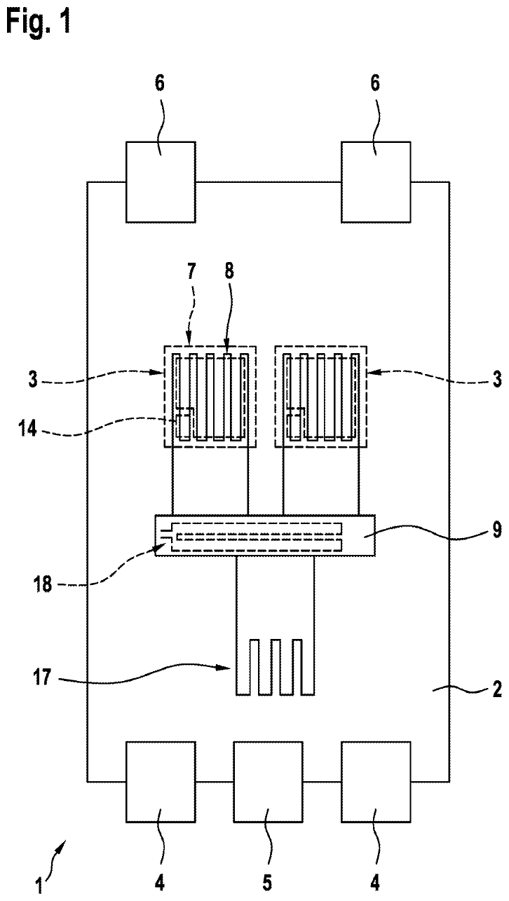

FIG. 1 shows an embodiment of a power module 1 according to the present invention, having a substrate 2 and a plurality of (here only two, as an example) power transistors 3 situated on a lower side of the substrate 2. FIG. 1 shows a view from the top side of the substrate 2, and the power transistors 3 on the opposite bottom side or in an inner substrate layer are therefore only shown in dashed lines.

The power module 1 includes five power terminals 4, 5, 6 connected to the substrate 2. The power terminals 4, 5, 6 can be connected, for example, to a respective source 7 and a gate 14 (each shown in dashed lines, because on the lower side of the substrate or embedded in the substrate) of a respective power transistor 3. For example, the power terminals 4 can provide a supply voltage, the power terminal 5 can provide a ground, and the power terminals 6 can be phase terminals. For simplicity, corresponding control electronics on substrate 2 are not shown here.

According to the present invention, here primary temperature sensors having conductor loops 8 for temperature measurement are situated on an upper side of the substrate 2 opposite the power transistors 3.

The conductor loops 8 have a meandering course, which makes it possible to increase the conductor path under the influence of the increased temperature and thus, for example, to achieve the greatest possible absolute effect on the resistance of the conductor loops 8. At the same time, material changes and thus resistance changes can also be detected in a wider range.

Here, the conductor loops 8 are situated substantially opposite the entire surface of the respective power transistor 3. However, the conductor loops 8 can also cover a larger area than the area of the respective power transformer 3 (e.g. an area 10-100% larger), in order to increase the measured absolute resistance change.

Alternatively, the area covered by the conductor loop 8 of the primary temperature sensor may be a different one. For example, the conductor loop 8 may substantially cover only the area of the source 7 of the power transistor 3 and thus not the gate 14, for example. In a field-effect transistor, the source 7 is usually the strongest heat source, and the conductor loop 8 can therefore only be situated opposite the source 7 for optimum sensitivity. However, the conductor loops can alternatively also be situated opposite another part of the power transistor 3. However, a conductor loop can also cover a plurality of power transistors 3 (even though this makes selective aging detection more difficult).

Further, the power module 1 has a reference temperature sensor having a conductor loop 17 for providing a comparison temperature of all power transistors 3, which are configured spaced apart on the upper side (or alternatively on one of the inner substrate layers).

The power module 1 includes an application-specific integrated circuit 9 (ASIC) connected to both (all) power transistors 3 and to the two (all) corresponding conductor loops 8. For example, the ASIC 9 can then use single-gate controlling to regulate the individual power transistors 3 in order to equalize the temperature load on the power transistors 3 (instantaneously or over time) and thus to increase the overall useful life of the power semiconductor. The ASIC 9 can be situated on the lower or upper side of the substrate (here for example on the upper side). In the latter case, the conductor loops 8 can for example be connected to the ASIC 9 via vias.

The power module moreover has a primary temperature sensor having a conductor loop 18 situated on a side of the substrate opposite the at least one application-specific integrated circuit 9 or in an inner substrate layer 12 situated below or above the at least one application-specific integrated circuit 9. Accordingly, the conductor loop 18 is also shown here in dashed lines, since it does not run on the upper side here. If the ASIC 9 is situated on an inner substrate layer 12 or the lower side of the substrate 2, the conductor loop 18 can also be situated on the upper side.

The conductor loops 8, 17, 18 can be connected and routed over a plurality of layers with vias in order to maximize the length in the hot area above the power transistor (e.g. MOSFET) or the ASIC 9. This can also generally increase the change in resistance of the conductor loops 8, 17, 18 with changes in temperature or material, thus improving the sensitivity of the present invention.

The conductor loops 8, 17, 18 are connected to the ASIC 9 at the two ends of the conductor loops 8, 17, 18 here only by way of example, but other types of connection are also possible (for example, for a four-point measurement) in order to enable higher accuracy of the resistance measurement.

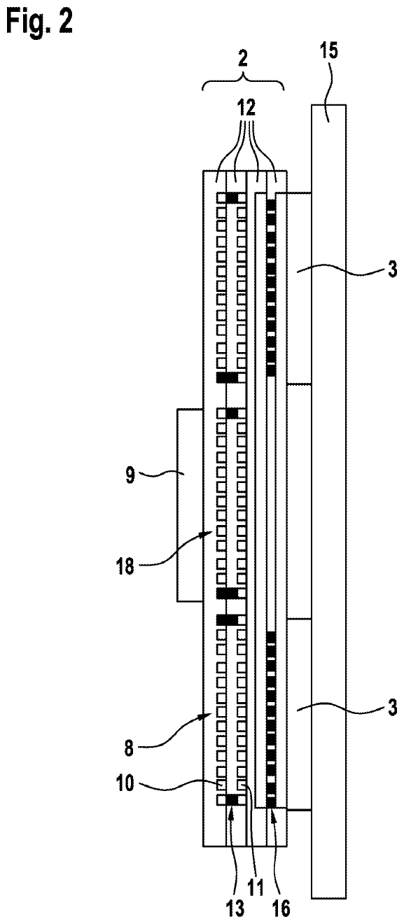

FIG. 2 shows a second embodiment of a power module 1 according to the present invention in cross-section through both conductor loops 8 and both power transistors 3 as well as through the conductor loop 18 of the primary temperature sensor of the ASIC 9. The upper side of substrate 2 is at the left in FIG. 2. The reference temperature sensor is not shown here for clarity (because not cut, for example), but it is present.

Here, the conductor loops 8 each have two conductor loop sections 10, 11 in two different substrate layers 12 for each power transistor 3 (correspondingly for conductor loop 18, or potentially for conductor loop 17 (not shown)). A meandering course of the conductor loop sections 10, 11 can only be surmised in this view, since each conductor loop (merely exemplary) is cut thirteen times. Here, the power module 1 has a first substrate 2 and a second substrate 15. Here, the first substrate 2 has four substrate layers 12, but two, three, five, or more substrate layers 12 are also possible. The power transistors 3 are embedded between the two substrates 2, 15 (in a sandwich construction, as it were).

The conductor loop sections 10, 11 are connected via vias 13 between the substrate layers 12. The power transistors 3 are further connected to power wirings 16, which are situated in particular in the 1-2 substrate layers 12 adjacent to the power transistors. Here the power wirings 16 are situated in different substrate layers 12 than the conductor loops 8 of the primary temperature sensors for temperature measurement/aging detection.

Although the present invention has been illustrated and described in detail on the basis of preferred exemplary embodiments, the present invention is not limited by the disclosed examples, and other variations may be derived therefrom by those skilled in the art without departing from the scope of protection of the present invention.

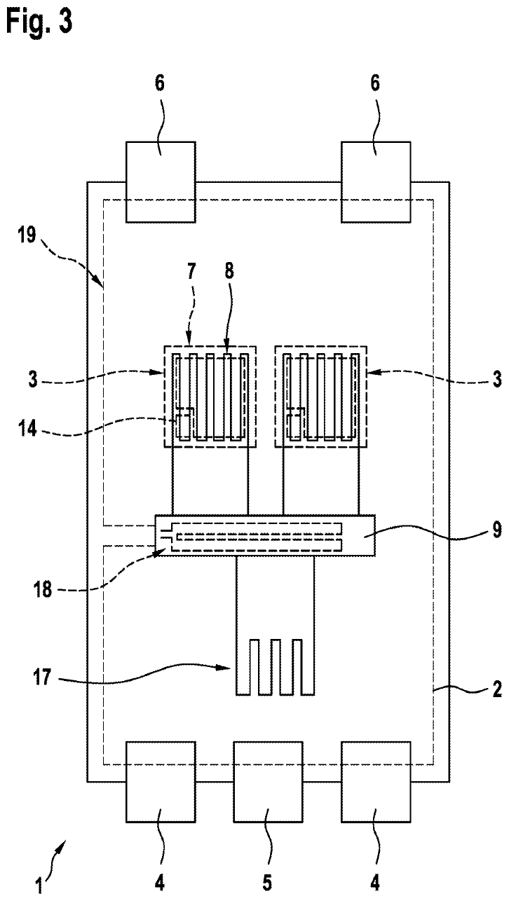

FIG. 3 shows a second embodiment of a power module 1 according to the present invention, which differs from the power module 1 of FIG. 1 only in that it has an edge conductor loop 19 extending substantially along an outer edge of the plane of the substrate 2. By the plane of the substrate is meant here the essentially planar rectangular shape of the power module 1, viewed perpendicularly in FIG. 3. The application-specific integrated circuit 9 is designed to detect, via periodic resistance measurements of the edge conductor loop 19, the presence of a break in the outer edge of the substrate 2 through an increase in resistance. The edge conductor loop 19 can be the conductor loop of the reference temperature sensor (e.g. instead of the conductor loop 17, also shown here) or (as shown here) an additional conductor loop primarily for break detection. Accordingly, as an alternative to FIG. 3, the conductor loop 17 can also be dispensed with, and the conductor loop 19 can be used for both the reference temperature sensor and the break detection.

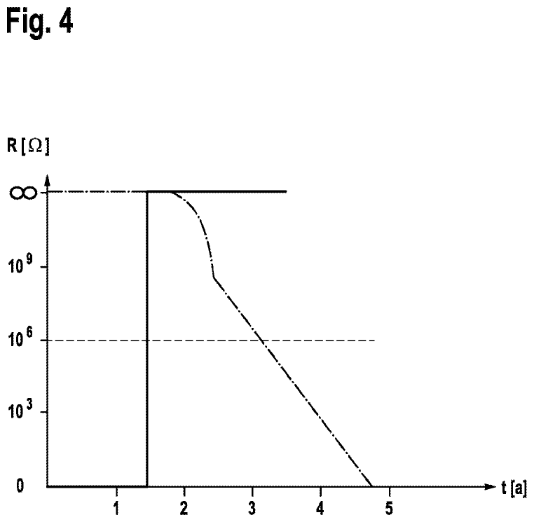

FIG. 4 illustrates how the temporal development of the measured resistances can be used to detect not only the aging of the power module (as described above, primarily via the drift of the temperature difference between the primary temperature sensor and the reference temperature sensor), but also a break in the material of the power module 1 and/or the penetration of moisture into the power module 1.

On the one hand, the application-specific integrated circuit is designed to detect the presence of moisture on or in the power module 1 via a resistance measurement between two conductor loops. This is shown schematically with the dash-dot curve in FIG. 4. First, the resistance between the two conductor loops is very high (shown in simplified form as infinite). If damage to the packaging or the substrate itself occurs over the years of operation of the power module 1, moisture may gradually penetrate, which can slowly reduce the resistance between the conductor loops. If the resistance falls below a limit value (here for example shown by a dashed line at 1 MΩ), the power module (e.g. the ASIC) can issue a warning in order to avoid a complete short circuit (with damage to other components) that might otherwise result. Thus, moisture detection by resistance change takes place gradually here and lies in a reduction of the resistance between two different conductor loops (which are initially electrically isolated), while for aging detection the temperature-dependent resistances measured in each of two different loops are each used to determine temperature, and then the temperature measurement values are used to determine a relative drift in order to determine the aging of the more heavily loaded conductor loop.

FIG. 4 also illustrates the break detection by the resistance curve of the solid line. For this purpose, the power module has, for example, an edge conductor loop 19 as shown in FIG. 3. In principle, however, break detection can be used for any conductor loop. The application-specific integrated circuit 9 is designed to detect the presence of a break (e.g. in the outer edge of the substrate) by a (sudden) increase in resistance, via regular resistance measurements of a single conductor loop. The application-specific integrated circuit 9 can be designed to detect, via regular resistance measurements of the edge conductor loop, the presence of a break in the outer edge of the substrate through an increase in resistance above a threshold value (e.g. 1 MΩ, as shown here as an example). The resistance of the conductor loop here is initially very low (simplified as practically zero, shown in the solid line) and then suddenly rises to well over 1 MΩ (simplified as infinite) due to a break in the conductor loop (and in the surrounding substrate), which signals a break in the conductor loop to ASIC 9. Here, for breakage detection the resistance of a single conductor loop is thus measured (without comparison to other conductor loops as in aging or moisture detection).

1-13. (canceled)

14. A power module, comprising:
a substrate;
at least one power transistor situated on the substrate; and
at least one temperature sensor situated in the power module, the at least one temperature sensor including at least one primary temperature sensor situated on a side of the substrate opposite the at least one power transistor or in an inner substrate layer situated above or below the at least one power transistor, and at least one reference temperature sensor configured to provide a comparison temperature and situated at a distance from all power transistors on one side of the substrate or on an inner substrate layer.

15. The power module as recited in claim 14, wherein the at least one primary temperature sensor includes a conductor loop for temperature measurement, which is situated on the side of the substrate opposite the at least one power transistor or in an inner substrate layer situated above or below the at least one power transistor.

16. The power module as recited in claim 14, further comprising at least one application-specific integrated circuit connected to a power transistor of the at least one power transistor, to the at least one primary temperature sensor associated with the power transistor, and to the reference temperature sensor.

17. The power module as recited in claim 16, wherein the application-specific integrated circuit is configured to calculate a measure of an aging of the power transistor via a comparison of temperature data provided by the at least one primary temperature sensor and the reference temperature sensor.

18. The power module as recited in claim 16, wherein the at least one power transistor includes at least two power transistors, and the at least one primary temperature sensor includes at least two primary temperature sensors corresponding to the at least two power transistors, and wherein the application-specific integrated circuit is connected to the at least two power transistors and the at least two corresponding primary temperature sensors.

19. The power module as recited in claim 16, wherein the at least one primary temperature sensor includes at least one primary temperature sensor situated on a side of the substrate opposite the at least one application-specific integrated circuit or in an inner substrate layer situated below or above the at least one application-specific integrated circuit.

20. The power module as recited in claim 18, wherein the application-specific integrated circuit is configured to control utilization of the at least two power transistors such that temperatures measured via the at least two corresponding primary temperature sensors are as equal as possible.

21. The power module as recited in claim 18, wherein the application-specific integrated circuit is configured to control at least one active cooling device of the power module such that temperatures measured via the at least two corresponding primary temperature sensors are as equal as possible.

22. The power module as recited in claim 16, wherein at least one primary temperature sensor of the at least one primary temperature sensor has at least one conductor loop attached to a load zone of the substrate, the conductor loop being connected to the application-specific integrated circuit, the application-specific integrated circuit being configured to calculate a measure of aging or damage of the load zone from a temporal development of an electrical resistance of the at least one conductor loop.

23. The power module as recited in claim 14, wherein the power module has at least one power semiconductor and at least one primary temperature sensor situated on a side of the substrate opposite the at least one power semiconductor or in an inner substrate layer situated above or below the at least one power semiconductor.

24. The power module as recited in claim 14, wherein the at least one primary temperature sensor and the at least one reference temperature sensor are connected in a Wheatstone bridge.

25. The power module as recited in claim 16, wherein the application-specific integrated circuit is configured to detect a presence of moisture on or in the power module via resistance measurements between two conductor loops.

26. The power module as recited in claim 16, wherein the power module has an edge conductor loop that extends substantially along an outer edge of a plane of the substrate, the application-specific integrated circuit being configured to detect, via regular resistance measurements of the edge conductor loop, a presence of a break in the outer edge of the substrate through an increase in resistance.
